(19) United States
(12) Patent Application Publication
(10) Pub. No.: US 2011/0147954 A1
(43) Pub. Date: Jun. 23, 2011

(54) SEMICONDUCTOR DEVICE, AND RESIN COMPOSITION USED FOR SEMICONDUCTOR DEVICE

(76) Inventor: Masahiro Kitamura, Tokyo (JP)

(21) Appl. No.: 13/060,182

(22) PCT Filed: Sep. 9, 2009
(86) PCT No.: PCT/JP2009/004447

§ 371 Date: Feb. 22, 2011

(30) Foreign Application Priority Data
Sep. 11, 2008 (JP) 2008-233026

(51) Int. Cl. H01L 23/28; C08L 63/02

(52) U.S. Cl. 257/789; 257/787; 257/793; 523/427; 257/E23.116

(57) ABSTRACT

A semiconductor device of the present invention (1) has a substrate (2); a semiconductor element (3) provided on at least one side of the substrate (2); a first resin (4) obtained by curing a first resin composition which fills a gap between the substrate (2) and the semiconductor element (3); and a second resin (5) which covers the substrate (2) and the first resin (4), and obtained by curing a second resin composition after the first resin composition is cured. In the present invention, adhesion strength between the first resin (4) and the second resin (5) is 18 MPa or larger at room temperature.

### TECHNICAL FIELD

The present invention relates to a semiconductor device, and resin composition used for the semiconductor device.

### BACKGROUND ART

With recent trends towards larger size of semiconductor elements, and larger number of pins and diversification of semiconductor devices, requirements for reliability of resin materials used for peripheral portion of the semiconductor elements have become more severe. While conventional semiconductor devices have most generally been configured so that a semiconductor element is bonded to a leadframe and then encapsulated with a resin, recent semiconductor devices have increasingly adopted ball grid array (BGA), for example, since increase in the number of pins has already reached the limit. Systems of bonding the semiconductor element, to be mounted to the BGA, to an interposer (substrate) includes a system of bonding the semiconductor element to the interposer by wire bonding, and a system of bonding the semiconductor element to the interposer by flip-chip bonding.

In the semiconductor device based on the system of bonding the semiconductor element to the interposer by flip-chip bonding, an underfill material is injected and filled in a gap between the substrate and the semiconductor element electrically connected thereto through bumps, for the purpose of improving the reliability.

The underfill material is generally composed of curable resin, hardener, filler and low-stress component, and fills up the gaps between the semiconductor element and the interposer of the semiconductor device, and between the bumps, typically making use of capillary action. For example, Patent Document 1 describes an underfill material containing a low-stress component. Patent Document 2 discloses a technique of improving close adherence and reliability of an epoxy resin composition used for encapsulation, by adding a low-stress component so as to adjust the elastic modulus of the cured article thereof within a predetermined range.

More recently, for the purpose of improving impact resistance and moisture resistance of the semiconductor device having the semiconductor element bonded to the interposer by flip-chip bonding, development has been made on a semiconductor device having the semiconductor element and the interposer encapsulated using the underfill material, and further encapsulated therearound using an encapsulation material used for transfer molding (referred to as molding material, hereinafter) (see Patent Document 3, for example).

The semiconductor device obtained by encapsulation using the underfill material, followed by further encapsulation around the semiconductor element using the molding material has, however, been suffering from a problem that separation could occur at the interface between the underfill material and the molding material, immediately after the encapsulation using the molding material, or in a severe environment where temperature largely varies (after reflow process or under drastic cold-hot temperature cycle). The separation accidentally occurred at the interface has been causative of propagation thereof towards the semiconductor element and the interposer, cracking of the semiconductor device, intrusion of moisture, and degradation of the reliability as a consequence. On the other hand, since the conventional underfill material contained the low-stress component, so that the low-stress component occasionally bloomed up to the surface of the cured article. This has resulted in degradation of close adherence between the underfill material and the molding material.
[Patent Document 1] Japanese Laid-Open Patent Publication No. 2003-212963
[Patent Document 2] Japanese Laid-Open Patent Publication No. 2004-256644
[Patent Document 3] Japanese Laid-Open Patent Publication No. 2001-326304

### DISCLOSURE OF THE INVENTION

It is therefore an object of the present invention to provide a semiconductor device configured as described in the above, having an excellent close adherence between the underfill material and the molding material which compose the semiconductor device, and improved in the reliability through prevention of internal defect.

The object described in the above may be accomplished by the present invention described below.

[1] A semiconductor device which includes: a substrate;

a semiconductor element provided on at least one side of the substrate; a first resin obtained by curing a first resin composition which fills a gap between the substrate, the semiconductor element and the semiconductor element; and a second resin which covers the substrate and the first resin, and obtained by curing a second resin composition after the first resin composition is cured, configured to ensure an adhesion strength between the first resin and the second resin of 18 MPa or larger at room temperature.

[2] The semiconductor device as described in [1], wherein the adhesion strength is 3 MPa or larger at 260° C.

[3] A semiconductor device which includes: a substrate; a semiconductor element provided on at least one side of the substrate; a first resin obtained by curing a first resin composition which fills the gap between the substrate and the semiconductor element; and a second resin which covers the substrate, the semiconductor element and the first resin, and obtained by curing a second resin composition after the first resin composition is cured, configured to ensure an adhesion strength between the first resin and the second resin of 3 MPa or larger at 260° C.

[4] The semiconductor device as described in any one of [1] to [3], wherein the adhesion strength is 7 MPa or larger at 175° C.

[5] The semiconductor device as described in any one of [1] to [4], wherein the first resin composition contains an epoxy resin which exists in liquid form at room temperature.

[6] The semiconductor device as described in any one of [1] to [5], wherein the first resin composition contains a bisphenol-type epoxy resin.

[7] The semiconductor device as described in any one of [1] to [6], wherein the first resin composition contains a multi-functional epoxy resin which has three or more epoxy groups per one molecule.

[8] The semiconductor device as described in any one of [1] to [7], wherein the first resin further contains a hardener and a filler, and excludes any low-stress component.

[9] The semiconductor device as described in [8], wherein the low-stress component is solid rubber, liquid rubber or elastomer.

[10] The semiconductor device as described in any one of [1] to [9], wherein the adhesion strength is 20 MPa or larger at room temperature.

[11] The semiconductor device as described in any one of [1] to [10], wherein the adhesion strength is 4 MPa or larger at 260° C.

[12] The semiconductor device as described in any one of [1] to [11], wherein the adhesion strength is 9 MPa or larger at 175° C.

[13] A semiconductor device comprising: a substrate; a semiconductor element provided on at least one side of the substrate; a first resin obtained by curing a first resin composition which fills the gap between the substrate and the semiconductor element; and a second resin which covers the substrate, the semiconductor element and the first resin, and obtained by curing a second resin composition after the first resin composition is cured, the first resin composition containing a multi-functional epoxy resin which has three or more epoxy groups per one molecule.

[14] The semiconductor device as described in [13], wherein the first resin further contains a hardener and a filler, and excludes any low-stress component.

[15] The semiconductor device as described in [14], wherein the low-stress component is solid rubber, liquid rubber or elastomer.

[16] The semiconductor device as described in any one of [1] to [15], wherein the first resin covers at least a part of side faces of the semiconductor element.

[17] The semiconductor device as described in any one of [1] to [16], wherein the semiconductor element has the top surface thereof remained exposed.

[18] The semiconductor device as described in any one of [13] to [17], wherein the multi-functional epoxy resin is a tri-functional, glycidylamine-type epoxy resin.

[19] The semiconductor device as described in any one of [8] to [12], and [14] to [18], wherein the filler is spherical silica.

[20] A resin composition filling the gap between the substrate and semiconductor element of the semiconductor device described in any one of [1] to [20].

According to the present invention, the reliability of the semiconductor device may be improved through enhancing close adherence between the first resin and the second resin.

### BRIEF DESCRIPTION OF THE DRAWINGS

FIG. 1 is a sectional view schematically illustrating an exemplary semiconductor device of the present invention;

FIG. 2 is a sectional view schematically illustrating an exemplary semiconductor device of the present invention;

FIG. 3 is a sectional view schematically illustrating an exemplary semiconductor device of the present invention;

FIG. 4 is a sectional view schematically illustrating an exemplary semiconductor device of the present invention; and

FIG. 5 is a sectional view schematically illustrating an exemplary method of manufacturing the semiconductor device of the present invention.

### BEST MODES FOR CARRYING OUT THE INVENTION

The semiconductor device of the present invention will be explained referring to preferred embodiments.

FIG. 1 is a sectional view schematically illustrating a semiconductor device of the present invention.

A semiconductor device 1 of the present invention has a substrate 2, a semiconductor element 3 provided on at least one side of the substrate 2, a first resin 4 obtained by curing a first resin composition which fills a gap between the substrate 2, the semiconductor element 3 and the semiconductor element 3, and a second resin 5 which covers the substrate 2 and the first resin 4, and obtained by curing a second resin composition after the first resin composition is cured. The semiconductor element 3 and the substrate 2 are connected through projection electrodes 6.

The present invention is characterized in that the adhesion strength between the first resin 4 and the second resin 5 is 18 MPa or larger at room temperature. For the case where the first resin 4 and the second resin 5 are composed of a thermosetting resin, the semiconductor device 1 will be increased in the internal stress in the course of cooling from the curing temperature to room temperature. If the interfacial adhesion strength between the first resin 4 and the second resin 5 is large at room temperature, separation at the interface between the first resin 4 and the second resin 5, due to increase in the internal stress, may be prevented, and thereby the reliability of the semiconductor device 1 may be improved. The adhesion strength between the first resin 4 and the second resin 5 at room temperature is preferably 20 MPa or larger, and is more preferably 24 MPa or larger. By the adjustment, the reliability of the semiconductor device 1 may further be improved.

In the present invention, the adhesion strength between the first resin 4 and the second resin 5 is preferably 3 MPa or larger at 260° C. A temperature of 260° C. is an upper limit temperature of a reflow furnace used for reflow bonding of lead-free bumps. If the adhesion strength at the interface between the first resin 4 and the second resin 5 is large at 260° C., the heat resistance and reliability of the semiconductor device 1 may be improved. The adhesion strength between the first resin 4 and the second resin 5 at 260° C. is more preferably 3.5 MPa or larger, and still more preferably 4 MPa or larger. By the selection, the heat resistance and reliability of the semiconductor device 1 may further be improved.

Moreover, in the present invention, the adhesion strength between the first resin 4 and the second resin 5 is preferably 7 MPa or larger at 175° C. A temperature of 175° C. is a post-curing temperature of general types of the second resin 5. If the adhesion strength at the interface between the first resin 4 and the second resin 5 is large at the post-curing temperature, the second resin composition may express an excellent close adherence to the first resin 4 in the course of curing, and thereby the reliability of the semiconductor device may be improved. The adhesion strength between the first resin 4 and the second resin at 175° C. is more preferably 8.5 MPa or larger, and still more preferably 9 MPa or larger. By the selection, the reliability of the semiconductor device 1 may further be improved.

Note that, according to the present invention, the semiconductor device 1 may express an excellent level of reliability even under a severe environment where the temperature largely varies, by keeping large adhesion strength between the first resin 4 and the second resin 5 over such wide temperature range. In particular, according to the present invention, the reliability of the semiconductor device 1 may further be improved by satisfying two or more levels of adhesion strength selected from those at 260° C., 175° C. and room temperature.

While method of measuring the adhesion strength is not specifically limited, a method described below was adopted to the present invention.

A first resin composition was coated over a 4-inch wafer (525 μm thick) at room temperature by spin coating, and the first resin composition was cured by a predetermined method, to thereby form the first resin. The wafer was then diced into semiconductor elements, and a second resin was formed at the center of the surface of the first resin, to thereby produce a sample to be measured. Alternatively, the semiconductor element may be subjected to plasma treatment if necessary, after the dicing.

Using the sample to be measured and an automatic adhesive strength measuring instrument, shear strength at room temperature and shear strength under heating (175° C., 260° C.) between the first resin and the second resin were measured.

The first resin 4 is a resin obtained after curing the first resin composition resin, and has a function of improving reliability of bonding between the substrate 2 and the semiconductor element 3.

In the present invention, the first resin composition contains, as a first curable resin, a multi-functional epoxy resin having three or more epoxy groups per one molecule. The multi-functional epoxy resin having three or more epoxy groups per one molecule may be exemplified by aromatic glycidylamine-type epoxy resins such as 4-(2,3-epoxypropoxy)-N,N-bis(2,3-epoxypropyl)-2-methylaniline, and N,N-bis(2,3-epoxypropyl)-4-(2,3-epoxypropoxy)aniline; multi-functional, orthocresol-novolac-type epoxy resin; multi-functional, dicyclopentadiene-type epoxy resin; and multi-functional, trisphenylmethane-type epoxy resin. By virtue of presence of three or more epoxy groups, the first resin composition may more robustly be cured, and the close adherence among the first resin 4 and the substrate 2 and the semiconductor element 3 may be improved. Accordingly, the adhesion strength among the first resin 4 and the second resin 5 may be enhanced, also by the encapsulation using the second resin composition explained below.

The multi-functional epoxy resin having three or more epoxy one molecule adoptable herein may be either of those exist in liquid form or solid format room temperature. Those exist in solid form at room temperature may preferably be used in a liquefied form, after being mixed with an epoxy resin which exists in liquid form at room temperature. The epoxy resin which exists in liquid form at room temperature may be exemplified by bisphenol-type diglycidylethers; glycidylether which exists in liquid form at room temperature, obtained by a reaction between phenol novolac and epichlorohydrin; aromatic glycidylamine-type epoxy resin; silicone-modified epoxy resin which exists in liquid form at room temperature; and mixture of these compounds. By the selection, the workability may be improved. In addition, the filling performance of, in particular, the first resin composition may be improved.

The first resin composition may further contain the first curable resin, and a first hardener described below.

The first curable resin may be exemplified by novolac-type phenol resins such as phenol novolac resin, cresol novolac resin, and bisphenol A novolac resin; phenol resins such as resol-type phenol resin; novolac-type epoxy resins such as phenol novolac-type epoxy resin, and cresol novolac-type epoxy resin; bisphenol-type epoxy resins such as bisphenol A-type epoxy resin, and bisphenol F-type epoxy resin; aromatic glycidylamine-type biepoxy resins such as N,N-diglycidylaniline, N,N-diglycidyltoluidine, diaminodiphenylmethane-type glycidylamine, and aminophenol-type glycidylamine; hydroquinone-type epoxy resin; biphenyl-type epoxy resin; stilbene-type epoxy resin; triphenol methane-type epoxy resin; triphenol propane-type epoxy resin; alkyl-modified triphenol methane-type epoxy resin; triazine nucleus-containing epoxy resin; dicyclopentadiene-modified, phenol-type epoxy resin; naphthol-type epoxy resin; naphthalene-type epoxy resin; phenol aralkyl-type epoxy resins having phenylene and/or biphenylene skeleton; aralkyl-type epoxy resins such as naphthol aralkyl-type epoxy resin having phenylene and/or biphenylene skeleton; aliphatic epoxy resin represented by alicyclic epoxys such as vinylcyclohexene oxide, dicyclopentadiene oxide, and alicyclic diepoxy-adipate; epoxy resins such as silicone-modified epoxy resin having disiloxane structure; urea resin; resins having triazine rings such as melamine resin; unsaturated polyester resin; bismaleimide resin; polyurethane resin; diallyl phthalate resin; silicone resin; resins having benzoxazine rings; and cyanate ester resin. These compounds may be used independently or in a mixed manner.

Alternatively, the above-described liquid epoxy resin may be used after being liquefied by mixing a crystalline epoxy resin which may exist in liquid form at room temperature but may crystallize if the purity thereof is sufficiently high, such as diglycidylether of dihydroxynaphthalene, and diglycidyl ether of tetramethylbiphenol.

Still alternatively, the above-described epoxy resin which exists in liquid form at room temperature may be used after being liquefied by mixing an epoxy resin which exists in solid form at room temperature. While content of the solid epoxy resin is not specifically limited, it is preferably 50% by weight or smaller of the whole epoxy resin, and particularly preferably 20% by weight or smaller. By adjusting the content within the above-described ranges, characteristics of the cured article of the first resin composition may more readily be controlled.

Note that the epoxy resin herein means the whole range of monomer, oligomer and polymer having two or more epoxy groups per one molecule.

While content of the first curable resin is not specifically limited, it is preferably 4 to 70% by weight of the whole portion of the first resin composition, and is particularly preferably 10 to 50% by weight. The workability and fluidity may be prevented from degrading by adjusting the content to the above-described lower limit value or above, whereas the heat-cycle resistance (crack resistance and prevention of deformation of solder) may be improved by adjusting the content to the above-described upper limit value or below.

The first hardener may be exemplified by aliphatic polyamines such as diethylenetriamine (DETA), triethylenetetramine (TETA), and metaxylylenediamine (MXDA); aromatic polyamines such as diaminodiphenylmethane (DDM), m-phenylenediamine (MPDA), diaminodiphenylsulfone (DDS), and a compound represented by the formula (1) below; amine-base hardeners such as dicyandiamide (DICY), and polyamine compound including organic acid dihydrazide; novolac-type phenol resins such as phenol novolac resin and cresol novolac resin; modified phenol resins such as triphenol methane-type phenol resin, terpene-modified phenol resin, and dicyclopentadiene-modified phenol resin; aralkyl-type phenol resins such as phenol aralkyl resin having a phenylene and/or biphenylene skeleton, and naphthol aralkyl resin having a phenylene and/or biphenylene skeleton; phenolic hardeners (all of monomers, oligomers, and polymers having two or more hydroxyl groups per one molecule) such as bisphenol compound, and alkyl and/or allyl-modified liquid polyphenol; alicyclic acid anhydrides (liquid acid anhydrides) such as hexahydrophthalic anhydride (HHPA), and methyltetrahydrophthalic anhydride (MTHPA); acid anhydride-base hardeners such as aromatic acid anhydrides including trimellitic anhydride (TMA), pyromellitic anhydride (PMDA), and benzophenonetetracarboxylic acid (BTDA); polyamide resin; and polysulfide resin.

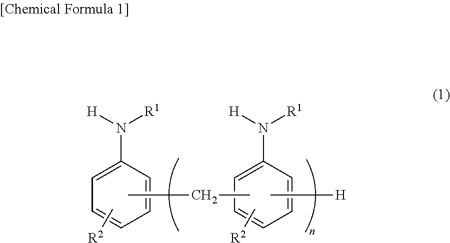

(In the formula, R¹ represents an alkyl group having 1 to 4 carbon atoms, R² represents any one of H, alkyl group having 1 to 3 carbon atoms and electron attractive group. R¹ and R² may be different from each other. n represents an integer.)

Among them, hardeners which exist in liquid form at room temperature are preferable. By the selection, the first resin composition may particularly be improved in the fluidity.

While content of the first hardener is not specifically limited, it is preferably 1 to 50% by weight of the whole portion of the first resin composition, and particularly preferably 3 to 40% by weight. By adjusting the content within the above-described ranges, the first resin composition may be cured in a particularly efficient manner.

The first resin composition preferably contains an inorganic filler, although not specifically limited. By virtue of the configuration, the moisture resistance and heat-cycle resistance (crack resistance and prevention of deformation of solder) may be improved.

The inorganic filler may be exemplified by silicates such as talc, calcined clay, uncalcined clay, mica, and glass; oxides such as titanium oxide, alumina, silica, and fused silica; carbonates such as calcium carbonate, magnesium carbonate, and hydrotalcite; hydroxides such as aluminum hydroxide, magnesium hydroxide, and calcium hydroxide; sulfates or sulfites such as barium sulfate, calcium sulfate, and calcium sulfite; borates such as zinc borate, barium metaborate, aluminum borate, calcium borate, and sodium borate; and nitrides such as aluminum nitride, boron nitride, and silicon nitride. Among them, the silica and fused silica are preferable, and spherical fused silica is particularly preferable. By the selection, the fluidity and stability in feeding may be improved.

While average particle size of the inorganic filler (in particular, spherical silica) is not specifically limited, it is preferably 10 μm or smaller, and particularly preferably 5 μm or smaller. By adjusting the average particle size within the above-described ranges, the first resin composition may particularly be improved in the filling performance.

The first resin composition is aimed at filling the gap between the semiconductor element and the substrate of the semiconductor device, typically making use of capillary action, where the gap is generally as large as 150 μm or narrower in most cases. For this reason, in view of ensuring a sufficient level of fluidity of the first resin composition in this sort of gap, the inorganic filler used for the first resin composition is preferably adjusted within the above-described ranges.

While content of the inorganic filler contained in the first resin composition is not specifically limited, it is preferably 30 to 90% by weight of the whole portion of the first resin composition, and is particularly preferably 40 to 75% by weight. The heat-cycle resistance (crack resistance and prevention of deformation of solder) may be prevented from degrading by adjusting the content to the above-described lower limit value or above, whereas the workability and fluidity may be improved by adjusting the content to the upper limit value or below.

While the total content of the first curable resin, the first hardener and the inorganic filler is not specifically limited, it is preferably 95% by weight or more of the whole portion of the first resin composition, and particularly preferably 97 to 99% by weight. In particular, an excellent level of close adherence at the interface between the first resin 4 and the second resin 5 may be accomplished by adjusting the content within the above-describe range. This is because any component, which possibly degrades the close adherence of the second resin 5, may be prevented from blooming up to the surface of the first resin 4.

The first resin composition preferably excludes any low-stress component. The low-stress component is aimed at preventing cracking at the encapsulated portion, through relaxing stress in the cured article of the resin composition. The low-stress component may be an elastic article such as rubber which include solid rubber, liquid rubber and elastomer (rubber elastomer), and may be exemplified by epoxy-modified butadiene rubber, vinyl-terminated butadiene rubber (VTBN), carboxyl terminated butadiene rubber (CTBN), acrylonitrile rubber, and polyamide.

In the present invention, the first resin composition preferably contains a multi-functional epoxy resin having three or more epoxy groups per one molecule, and excludes any low-stress component. While the resin in the prior art has occasionally been suffering from blooming of the low-stress component contained therein onto the surface, the first resin in the present invention successfully improves the close adherence with respect to the second resin, as a result of exclusion of the low-stress component.

The first resin composition may be added with additives such as curing accelerator, coupling agent, pigment, dye, leveling agent, anti-foaming agent and so forth, so far as the purpose of the present invention will not adversely be affected.

The second resin 5 is a resin obtained by curing the second resin composition, and has a function of protecting the semiconductor element 3.

The second resin composition contains a second curable resin and a second hardener.

The second curable resin may be exemplified by novolac-type phenol resins such as phenol novolac resin, cresol novolac resin, and bisphenol A novolac resin; phenol resins such as resol-type phenol resin; novolac-type epoxy resin such as phenol novolac-type epoxy resin, and cresol novolac-type epoxy resin; bisphenol-type epoxy resins such as bisphenol A-type epoxy resin, and bisphenol F-type epoxy resin; hydroquinone-type epoxy resin; biphenyl-type epoxy resin; stilbene-type epoxy resin; triphenolmethane-type epoxy resin; alkyl-modified triphenolmethane-type epoxy resin; triazine nuclei-containing epoxy resin; dicyclopentadiene-modified, phenol-type epoxy resin; naphthol-type epoxy resin; naphthalene-type epoxy resin; phenol aralkyl-type epoxy resin having a phenylene and/or biphenylene skeleton; epoxy resins such as aralkyl-type epoxy resins such as naphthol aralkyl-type epoxy resin having a phenylene and/or biphenylene skeleton; urea resin; resins such as melamine resin having triazine rings; unsaturated polyester resin; bismaleimide resin; polyurethane resin; diallyl phthalate resin; silicone resin; resins having benzoxazine rings, and cyanate ester resin. These compounds may be used independently or in a mixed manner. Note that the epoxy resin herein means the whole range of monomer, oligomer and polymer having two or more epoxy groups per one molecule. Among them, epoxy resin is preferable. By the selection, electrical characteristics may be improved. In addition, it may keep fluidity necessary for molding, even after being added with a large amount of inorganic filler.

While content of the second curable resin is not specifically limited, it is preferably 3 to 30% by weight of the whole portion of the second resin composition, and is particularly preferably 5 to 20% by weight. By adjusting the content to the above-described lower limit value or above, the fluidity may be prevented from degrading, and thereby the semiconductor element may be encapsulated in a successful manner. On the other hand, by adjusting the content to the above-described upper limit value or below, the heat resistance of solder may be prevented from degrading.

The second hardener may be exemplified by aliphatic polyamines such as diethylenetriamine (DETA), triethylenetetramine (TETA), and metaxylylenediamine (MXDA); aromatic polyamines such as diaminodiphenylmethane (DDM), m-phenylenediamine (MPDA), diaminodiphenylsulfone (DDS); amine-base hardeners such as dicyandiamide (DICY), and polyamine compounds including organic acid dihyrazide; phenolic hardeners (hardeners having phenolic hydroxyl groups) such as novolac-type phenol resin, and phenol polymer; alicyclic acid anhydrides (liquid acid anhydrides) such as hexahydrophthalic anhydride (HHPA), and methyltetrahydrophthalic anhydride (MTHPA); acid anhydride-base hardeners such as aromatic acid anhydrides including trimellitic anhydride (TMA), pyromellitic anhydride (PMDA), and benzophenonetetracarboxylic acid (BTDA); polyamide resin; and polysulfide resin.

While the second hardener, adoptable to the case where the above-described epoxy resin is used as the second curable resin, is not specifically limited, hardeners having phenolic hydroxyl groups are preferably adoptable. The hardeners having phenolic hydroxyl groups may more readily control reaction of the second resin as compared with other hardeners, and thereby a desirable level of fluidity may be ensured in the process of manufacturing the semiconductor device. The hardeners having phenolic hydroxyl groups may also allow increase in the content of inorganic filler, by virtue of their easy controllability of reactivity. Accordingly, an excellent level of reliability of the semiconductor device may be ensured. The hardeners having phenolic hydroxyl groups herein mean the whole range of monomer, oligomer and polymer having two or more phenolic hydroxyl groups per one molecule, without limitations on their molecular weight and molecular structure. Specific examples include novolac-type phenol resins such as phenol novolac resin, and cresol novolac resin; modified phenol resins such as triphenolmethane-type phenol resin, terpene-modified phenol resin, and dicyclopentadiene-modified phenol resin; phenol aralkyl resin having a phenylene and/or biphenylene skeleton; aralkyl-type phenol resin such as naphthol aralkyl resin having a phenylene and/or biphenylene skeleton; and bisphenol compounds. These compounds may be used independently or in a mixed manner.

While content of the second hardener is not specifically limited, it is preferably 2 to 10% by weight of the whole portion of the second resin composition, and is particularly preferably 4 to 7% by weight. By adjusting the content to the above-described lower limit value or above, the fluidity is improved, and thereby the close adherence to the first resin may be improved. On the other hand, by adjusting the content to the above-described upper limit value or below, increase in the moisture absorption may be suppressed, and thereby the close adherence to the first resin after reflow may be improved.

For the case where the second curable resin is the epoxy resin, the hardener having phenolic hydroxyl groups may preferably be adopted. While equivalence ratio of the epoxy groups of the epoxy resin and the phenolic hydroxyl groups of the hardener having the phenolic hydroxyl groups (epoxy group/phenolic hydroxyl group) is not specifically limited, it is preferably 0.5 to 2.0, and particularly preferably 0.7 to 1.5. By adjusting the equivalence ratio within the above-described ranges, the second resin is excellent in particular in the curability and the anti-moisture reliability.

While the second curable resin and the first curable resin are not specifically limited, they are preferably composed of the same species of curable resin. By this configuration, the close adherence at the interface between the second resin and the first resin may be improved.

The curable resin of the same species may be exemplified by the same species of epoxy resin, and the same species of phenol resin. Among them, the same species of epoxy resin is preferable. By the selection, excellent levels of both of the heat resistance and electric characteristics may be obtained.

The second resin composition preferably contains an inorganic filler, although not specifically limited. The inorganic filler may be exemplified by silicates such as talc, calcined clay, uncalcined clay, mica, and glass; oxides such as titanium oxide, alumina, silica powder of fused silica (fused spherical silica, crushed fused silica) and crystalline silica; carbonates such as calcium carbonate, magnesium carbonate, and hydrotalcite; hydroxides such as aluminum hydroxide, magnesium hydroxide, and calcium hydroxide; sulfates or sulfites such as barium sulfate, calcium sulfate, and calcium sulfite; borates such as zinc borate, barium metaborate, aluminum borate, calcium borate, and sodium borate; and nitrides such as aluminum nitride, boron nitride, and silicon nitride. The inorganic filler may be used independently or in a mixed manner. Among them, the silica powders of fused silica, crystalline silica and so forth are preferable, and spherical fused silica is particularly preferable. By the selection, the heat resistance, moisture resistance, strength and so forth may be improved. While geometry of the inorganic filler is not specifically limited, it is spherical, preferably with a broad distribution of particle size. By virtue of this configuration, the fluidity of the second resin composition may particularly be improved. Moreover, the inorganic filler may have the surface treated with a coupling agent.

While content of the inorganic filler contained in the second resin composition is not specifically limited, it is preferably 20 to 95% by weight of the whole portion of the second resin composition, and particularly preferably 30 to 90% by weight. The moisture resistance may be suppressed from degrading through adjustment of the content to the above-described lower limit value or above, and a desirable level of fluidity may be ensured through adjustment of the content to the above-described upper limit value or below.

So far as the object of the present invention is not adversely affected, the second resin composition may be added with additives such as diazabicycloalkenes and derivatives thereof, such as 1,8-diazabicyclo(5,4,0)undecene-7; amine-base compounds such as tributylamine, and benzyldimethylamine; imidazole compounds such as 2-methylimidazole; organic phosphines such as triphenylphosphine, and methyldiphenylphosphine; curing accelerators such as tetra-substituted phosphonium tetra-substituted borates such as tetetraphenylphosphonium tetraphenyl borate, tetraphenylphosphonium tetrabenzoic acid borate, tetraphenylphosphonium tetranaphthoic acid borate, tetraphenylphosphonium tetranaphtoyloxy borate, and tetraphenylphosphonium tetranaphthyloxy borate; silane coupling agents such as epoxysilane, mercaptosilane, aminosilane, alkylsilane, ureidosilane, and vinylsilane; coupling agents such as titanate coupling agent, aluminum coupling agent, and aluminum/zirconium coupling agent; colarants such as carbon black, and red iron oxide; natural waxes such as carnauba wax; synthetic wax such as polyethylene wax; higher aliphatic acids and metal salts of them such as stearic acid and zinc stearate; mold-releasing agents such as paraffin; stress-reducing agents such as silicone oil, and silicone rubber; flame retarders such as brominated epoxy resin, antimony trioxide, aluminum hydroxide, magnesium hydroxide, zinc borate, zinc molybdate, and phosphazene; and inorganic ion exchangers such as hydrate of bismuth oxide.

While the second resin composition used for the present invention is not specifically limited, epoxy resin encapsulation materials for area-mounting-type device are suitable for single-sided molded semiconductor devices illustrated in FIGS. 1 to 3, and may be exemplified by epoxy resin encapsulation materials available from Sumitomo Bakelite Co., Ltd. under the trade names of G750 Series, G760 Series, G770 Series, and G790 Series.

The semiconductor device used for the present invention is obtained by opposingly disposing the semiconductor element 3 on the substrate 2 while keeping a gap in between, connecting the semiconductor element 3 through the projection electrodes 6, filling the gap between the semiconductor element 3 and the substrate 2 with the first resin composition, and then encapsulating the periphery thereof with the second resin composition.

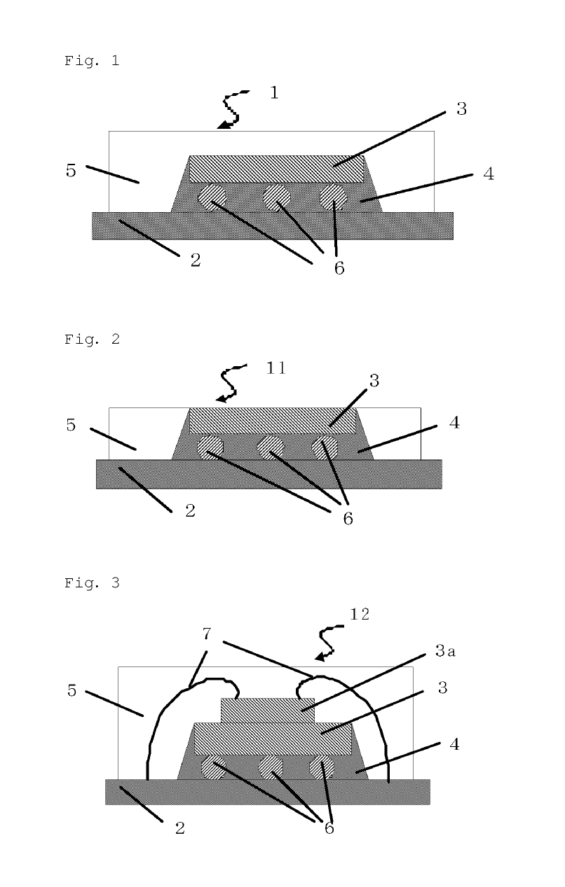

Note that the semiconductor device of the present invention may also be adoptable to semiconductor devices having configurations other than that illustrated in FIG. 1. The semiconductor devices having other configurations may be exemplified by those typically illustrated in FIG. 2 to FIG. 4. FIG. 2 to FIG. 4 are schematic drawings of the semiconductor devices having other configurations. Explanation below will be given mainly on aspects different from those of the semiconductor device illustrated in FIG. 1.

A semiconductor device 11 illustrated in FIG. 2 is configured so that the semiconductor element 3 is opposingly disposed on the substrate 2 while keeping a gap in between, the semiconductor element 3 is connected through the projection electrodes 6, the gap between the semiconductor element 3 and the substrate 2 is filled up with the first resin composition, and the second resin 5 is formed so as to leave the top surface of the semiconductor element 3 uncovered. In other words, the side faces of the semiconductor element 3 is surrounded by the second resin 5 over the entire circumference thereof.

A semiconductor device 12 illustrated in FIG. 3 is configured so that the semiconductor element 3 is opposingly disposed on the substrate 2 while keeping a gap in between, the semiconductor element 3 is connected through the projection electrodes 6, the gap between the semiconductor element 3 and the substrate 2 is filled up with the first resin composition, another semiconductor element 3a is mounted on the top surface of the semiconductor device 3, while placing an adhesive, adhesive film or the like (not illustrated) in between, the semiconductor element 3a is connected to the substrate 2 through wires 7 by wire bonding, and the product is encapsulated with the second resin composition.

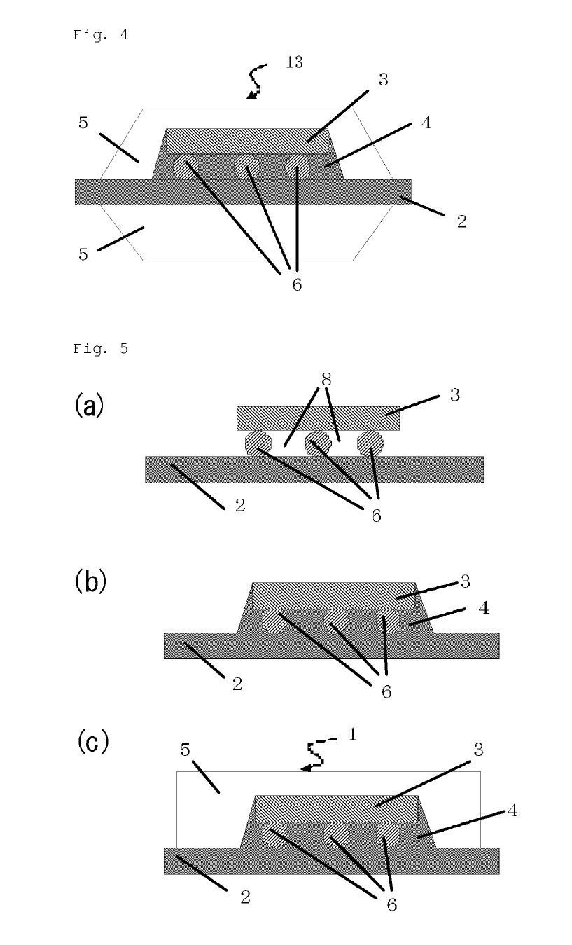

A semiconductor device 13 illustrated in FIG. 4 is configured so that a second resin 5 is additionally formed on the substrate 2 on the surface thereof opposite to that having the semiconductor element 3 mounted thereon.

Note that, also in FIG. 2 to FIG. 4, resin compositions of the first resin 4 and the second resin 5 are same as those of the semiconductor device 1 illustrated in FIG. 1.

Among the above-described configurations of the semiconductor device, the present invention is preferably applicable to the configurations typically illustrated in FIGS. 1 to 3, in which only one side of the substrate 2 is encapsulated by the second resin composition. Since the single-sided encapsulation causes larger changes in the amount of warping relative to changes in temperature of the semiconductor device, as compared with the case where both surfaces of the substrate 2 are encapsulated by the second resin composition, so that the interface between the first resin 4 and the second resin 5 will be applied with a large stress, and consequently needs larger adhesive force.

Next, a method of manufacturing the semiconductor device 1 illustrated in FIG. 1 will be explained.

FIG. 5 is a schematic drawing illustrating an exemplary method of manufacturing the semiconductor device 1 of the present invention.

To the method of manufacturing the semiconductor device 1, the substrate 2, having the semiconductor element 3 preliminarily provided on one side thereof as illustrated in FIG. 5(a), may be used.

First, the first resin composition is filled in a gap 8 between the substrate 2, and the semiconductor element 3 provided on one side of the substrate 2. An exemplary method of filling the first resin composition may be such as placing the semiconductor device on a hot plate, placing the first resin composition in the vicinity of the semiconductor element 3 using an injection tool such as syringe containing the first resin composition, and allowing the resin to intrude into the gap 8 based on capillary action to thereby fill it up.

The first resin composition may be obtained by mixing the above-described first thermosetting resin, first hardener and so forth typically using a roll mixer or planetary mixer, preferably followed by vacuum degassing.

While viscosity of the first resin composition (fill-up liquid) is not specifically limited, it is preferably 0.5 Pa·s or above, and more preferably 1 Pa·s or above. By the adjustment, the resin composition may be prevented from trailing from a nozzle of a filling apparatus. The viscosity is 500 Pa·s or smaller, and more preferably 200 Pa·s or smaller. By the adjustment, a desirable level of fluidity may be obtained.

The viscosity may be evaluated at normal temperature (25° C.) using Brookfield viscometer, E-type viscometer or the like, at a condition of measurement of 0.5 to 5 rpm.

As illustrated in FIG. 5(b), the first resin composition is cured after it was confirmed to fill up the gap 8. Methods of curing the first resin composition may be exemplified by heating, and irradiation of light. While conditions of heating in the heating method are not specifically limited, they may preferably be 140 to 180° C. for 10 to 180 minutes, and particularly preferably 150 to 165° C. for 30 to 120 minutes. The resin may thoroughly be cured by adjusting the heating conditions to the above-described lower limit values or above, and the productivity may be improved by adjusting them to the above-described upper limit values or below.

Next, the product is encapsulated with the second resin, so as to surround the semiconductor element 3, and the first resin 4 obtained by curing the first resin composition. Methods of encapsulation using the second resin composition may be exemplified by transfer molding, compression molding, and injection molding.

The second resin composition may be obtained by thoroughly mixing the source materials typically using a mixer, by kneading under fusion using a mixing machine such as heat roll mill, kneader and extruder, and by crushing after being cooled.

While viscosity of the second resin composition in the process of encapsulation is not specifically limited, it is adjusted to 30 poise or above, and more preferably to 50 poise or above. By the adjustment, a desirable level of fluidity may be obtained, enough to improve close adherence to the first resin. The viscosity is adjusted to 300 poise or below, and more preferably to 200 poise or below. By the adjustment, voids may be prevented from being produced. The viscosity may be determined typically by using Koka-type flowtester.

Then, as illustrated in FIG. 5(c), the product is encapsulated with the second resin composition, and the second resin composition is cured. Method of curing the second resin composition may be exemplified by heating, and irradiation of light.

While conditions of heating in the heating method are not specifically limited, they may preferably be 160 to 185° C. for 30 to 180 seconds, and particularly preferably 170 to 185° C. for 50 to 120 seconds. Mold-releasing defects such as capturing of runners in the dies may be prevented from occurring by adjusting the conditions of heating to the above-described lower limit values or above, and the productivity may be improved through shortening of the cycle time of molding by adjusting the conditions of heating to the above-described upper limit values or below.

It is also preferable to subject the second resin composition, after being cured under heating, to further heating for post curing.

Alternatively, in the method of manufacturing the semiconductor device 1, the first resin composition after curing may be subjected to plasma treatment before the encapsulation with the second resin composition. By the plasma treatment, any components blooming on the surface of the first resin 4, which possibly degrade the close adherence to the second resin 5, may be removed, and the surface of the first resin 4 is roughened, enough to obtain better close adherence at the interface between the first resin 4 and the second resin 5.

The semiconductor device 1 may be obtained by the method described in the above. While the above-described method dealt with the case where the second resin 5 completely encapsulated the periphery of the semiconductor element 3 on one side of the substrate 2, the present invention is not limited thereto. More specifically, other possible cases may be such as surrounding the entire circumference of at least the side faces of the semiconductor element 3, and such as providing encapsulation with the second resin 5 on both sides of the substrate 2.

### EXAMPLES

The present invention will be detailed below referring to Examples and Comparative Example, without limiting the present invention.

### Example 1

### (1) Preparation of First Resin Composition

First resin composition A composing the first resin was obtained by kneading 11.8% by weight of bisphenol F-type epoxy resin (RE-403S from NIPPON KAYAKU Co., Ltd., epoxide equivalent weight=165) and 11.8% by weight of 4-(2,3-epoxypropoxy)-N,N-bis(2,3-epoxypropyl)-2-methylaniline (ELM-100 from Sumitomo Chemical Co., Ltd., epoxide equivalent weight=100), both of which adopted as the first curable resin, 12.1% by weight of 3,3′-diethyl-4,4′-diaminodiphenylmethane (Kayahard AA from NIPPON KAYAKU Co., Ltd., equivalent weight=63.5) adopted as the first hardener, 63.0% by weight of spherical silica (SO-E3 from Admatechs Co., Ltd., average particle size=1 μm) adopted as the inorganic filler, 1.2% by weight of γ-glycidoxypropyltrimethoxysilane (KBM-403 from Shin-Etsu Chemical Co., Ltd.) adopted as the coupling agent, and 0.1% by weight of carbon black (MA-600 from Mitsubishi Chemical Corporation) adopted as the pigment, using a three-roll mill at room temperature, and by deforming the mixture in vacuo using a vacuum degassing apparatus.

### (2) Second Resin Composition

Sumicon EME-G770 (from Sumitomo Bakelite Co., Ltd.), which is an epoxy resin encapsulation material, was used as the second resin composition.

### (3) Manufacturing of Semiconductor Device

(3-1) Filling (Encapsulation) with First Resin Composition

A semiconductor element and a substrate adopted herein are such as those below.

A substrate having semiconductor element preliminarily mounted thereon was used as the substrate. The semiconductor element adopted herein has a size of 10 mm×10 mm×0.35 mm (thickness), and the substrate was a 352-pin BGA (having a size of 35 mm×35 mm×0.56 mm (thickness), composed of a bismaleimide-triazine resin/glass cloth substrate with gold-plated gate and runners). The semiconductor element and the substrate were peripherally bonded through 176 solder bumps arranged in the circumferential area. Height of the solder bumps was 0.05 mm. Silicon nitride was used for a protective film of the semiconductor element, and PSR4000 from Taiyo Ink Mfg. Co., Ltd. was used as a solder resist coated over the substrate.

The substrate having the semiconductor element mounted thereon was heated on a hot plate at 110° C., the first resin composition was placed on one edge of the semiconductor element using a dispenser for filling, and the first resin composition was cured in an oven at 150° C. for 120 minutes, to thereby form the first resin.

### (3-2) Plasma Treatment

The first resin composition after cured was subjected to plasma treatment before encapsulation with the second resin composition. A plasma apparatus adopted herein was AP-1000 from March Plasma Systems, Inc. using Ar as a gas species at a flow rate of 200 sccm, at a power of treatment of 400 W for 120 seconds, under the direct plasma mode.

(3-3) Filling (Encapsulation) with Second Resin Composition

The second resin composition was molded for encapsulation using a transfer molding machine, at a die temperature of 175° C., an injection pressure of 7.8 MPa, a curing time of 2 minutes, and then post-cured at 175° C. for 2 hours so as to form the second resin, and thereby the semiconductor device was obtained. Two types of semiconductor devices, illustrated in FIG. 1 and FIG. 2, were manufactured.

The first resin composition, the second resin composition, and the semiconductor devices obtained in the above were evaluated as described below. Items and details of evaluation will be explained below. Results were shown in Table 1.

### [Items of Evaluation]

### (1) Adhesion Strength

The first resin composition prepared in the above was coated on a 4-inch wafer (525 μm thick) at room temperature by spin coating, the first resin composition was then cured in an oven at 150° C. for 120 minutes, to thereby form the first resin on the wafer. The wafer was then diced into 6 mm×6 mm chips, and then subjected to plasma treatment. A plasma apparatus adopted herein was AP-1000 from March Plasma Systems, Inc. using Ar as a gas species at a flow rate of 200 sccm, at a power of treatment of 400 W for 120 seconds, under the direct plasma mode.

Thereafter, a mold article of the second resin, having a size of 2 mm×2 mm and a height of 5 mm, was formed at the center on the surface of each of the 6 mm×6 mm first resin, by transfer molding at a die temperature of 175° C., an injection pressure of 7.8 MPa, and a curing time of 2 minutes, the product was then post-cured at 175° C. for 2 hours, to thereby form the second resin. Samples to be measured were thus formed.

Using an automatic adhesive strength measuring instrument, shear strength at room temperature and shear strength under heating (175° C., 260° C.) of the first resin and the second resin were measured. Values were expressed in MPa. Results were shown in Table 1.

### (2) Adhesiveness

Ten pieces each of two types of semiconductor devices obtained in the above were subjected to moisture absorption treatment (30° C., 60%, 192 hours), reflow resistance test (conforming to JEDEC condition at 260° C.) repeated three times, and thermal impact test (1000 cycles between −55° C. for 30 minutes and 125° C. for 30 minutes), and then observed using a scanning acoustic tomograph (SAT) with respect to separation at the interface between the underfill material (first resin) and the molding material (second resin), and evaluated based on the number of semiconductor devices found to cause separation.

### (3) Heat Resistance of Solder

Heat resistance of solder was evaluated using ten pieces each of two types of semiconductor devices obtained in the above, by subjecting them to moisture absorption treatment (30° C., 60%, 192 hours), reflow resistance test (conforming to JEDEC condition at 260° C.) repeated three times, and thermal impact test (1000 cycles between −55° C. for 30 minutes and 125° C. for 30 minutes), and then observed with respect to state of separation between the semiconductor element and the first resin, and between the underfill material (first resin) and the molding material (second resin). Symbols mean the followings:

Good: sample found to have no separation;
1: sample found to have no separation between the semiconductor element and the first resin, but have separation between the first resin and the second resin;
2: sample found to have separation between the semiconductor element and the first resin, but have no separation between the first resin and the second resin; and
3: sample found to have separation between the semiconductor element and the first resin, and also between the first resin and the second resin.

### (4) Judgment of Semiconductor Devices

Reliability of the semiconductor device was judged overall based on the adhesiveness and heat resistance of solder described in the above.

### Example 2

Processes were conducted similarly to Example 1, except that Sumicon EME-G760 (from Sumitomo Bakelite Co., Ltd.), which is an epoxy resin encapsulation material, was used as the second resin composition.

### Example 3

Processes were conducted similarly to Example 1, except that Sumicon EME-G790 (from Sumitomo Bakelite Co., Ltd.), which is an epoxy resin encapsulation material, was used as the second resin composition.

### Example 4

Processes were conducted similarly to Example 1, except that ingredients of the first resin composition were modified as described below.

First resin composition B composing the first resin was obtained by kneading 9.5% by weight of bisphenol F-type epoxy resin (RE-403S from NIPPON KAYAKU Co., Ltd., epoxide equivalent weight=165) and 9.5% by weight of 4-(2,3-epoxypropoxy)-N,N-bis(2,3-epoxypropyl)-2-methylaniline (ELM-100 from Sumitomo Chemical Co., Ltd., epoxide equivalent weight=100), both of which adopted as the first curable resin, 16.5% by weight of liquid polyphenol (MEH-8000H from Meiwa Plastic Industry, Ltd., hyroxyl group equivalent weight=141) adopted as the first hardener, 63.0% by weight of spherical silica (SO-E3 from Admatechs Co., Ltd., average particle size=1 μm) adopted as the inorganic filler, 0.9% by weight of γ-glycidoxypropyltrimethoxysilane (KBM-403 from Shin-Etsu Chemical Co., Ltd.) adopted as the coupling agent, 0.1% by weight of carbon black (MA-600 from Mitsubishi Chemical Corporation) adopted as the pigment, and 0.5% by weight of 2-phenyl-4-methylimidazole adopted as the hardening accelerator, using a three-roll mill at room temperature, and by deforming the mixture in vacuo using a vacuum degassing apparatus.

### Example 5

Processes were conducted similarly to Example 1, except that ingredients of the first resin composition were modified as described below.

First resin composition C composing the first resin was obtained by kneading 15.7% by weight of bisphenol F-type epoxy resin (RE-403S from NIPPON KAYAKU Co., Ltd., epoxide equivalent weight=165) and 8.5% by weight of N,N-bis(2,3-epoxypropyl)-4-(2,3-epoxypropoxy) aniline (jER-630 from Japan Epoxy Resins Co., Ltd.), both of which adopted as the first curable resin, 11.5% by weight of 3,3′-diethyl-4,4′-diaminodiphenylmethane (Kayahard AA from NIPPON KAYAKU Co., Ltd., equivalent weight=63.5) adopted as the first hardener, 63.0% by weight of spherical silica (SO-E3 from Admatechs Co., Ltd., average particle size=1 μm) adopted as the inorganic filler, 1.2% by weight of γ-glycidoxypropyltrimethoxysilane (KBM-403 from Shin-Etsu Chemical Co., Ltd.) adopted as the coupling agent, and 0.1% by weight of carbon black (MA-600 from Mitsubishi Chemical Corporation) adopted as the pibment, using a three-roll mill at room temperature, and by deforming the mixture in vacuo using a vacuum degassing apparatus.

### Comparative Example 1

Processes were conducted similarly to Example 1, except that ingredients of the first resin composition were modified as described below.

First resin composition D composing the first resin was obtained by kneading 26.6% by weight of bisphenol F-type epoxy resin (RE-403S from NIPPON KAYAKU Co., Ltd., epoxide equivalent weight=165) adopted as the first curable resin, 10.4% by weight of 3,3′-diethyl-4,4′-diaminodiphenylmethane (Kayahard AA from NIPPON KAYAKU Co., Ltd., equivalent weight=63.5) adopted as the first hardener, 60.0% by weight of spherical silica (SO-E3 from Admatechs Co., Ltd., average particle size=1 μm) adopted as the inorganic filler, 1.3% by weight γ-glycidoxypropyltrimethoxysilane (KBM-403 from Shin-Etsu Chemical Co., Ltd.) adopted as the coupling agent, 0.1% by weight of carbon black (MA-600 from Mitsubishi Chemical Corporation) adopted as the pigment, and 1.6% by weight of VTBN (VTBNX1300X33 from Ube Industries, Ltd.) adopted as the low-stress component, using a three-roll mill at room temperature, and by deforming the mixture in vacuo using a vacuum degassing apparatus.

TABLE 1

| | Example | Example | Example | Example | Example | Comparative |
|---|---|---|---|---|---|---|
| | 1 | 2 | 3 | 4 | 5 | Example 1 |
| First resin | A | A | A | B | C | D |
| composition | | | | | | |
| Second resin | G770 | G760 | G790 | G770 | G770 | G770 |
| composition | | | | | | |
| Adhesion strength | 5.3 | 8.3 | 5.3 | 4.0 | 5.5 | 1.5 |
| (260° C.) [MPa] | | | | | | |
| Adhesion strength | 11.5 | 32.8 | 21.3 | 9.1 | 11.6 | 2.9 |
| (170° C.) [MPa] | | | | | | |
| Adhesion strength | 42.0 | 42.5 | 36.3 | 24.3 | 41.5 | 9.1 |
| (room temperature) | | | | | | |
| [MPa] | | | | | | |
| Adhesiveness | 0/20 | 0/20 | 0/20 | 0/20 | 0/20 | 20/20 |
| (sample/total) | | | | | | |
| Heat resistance of | Good | Good | Good | Good | Good | ×1 |
| solder | | | | | | |
| Judgment | Good | Good | Good | Good | Good | No good |

As is clear from Table 1, Examples 1 to 5 were found to be excellent in the adhesiveness between the first resin and the second resin, and that the semiconductor devices were found to be improved in the reliability.

This application is based on Japanese patent application No. 2008-233026 filed on Sep. 11, 2008, the entire content of which is incorporated hereinto by reference.

1.-20. (canceled)

21. A semiconductor device comprising:
a substrate;
a semiconductor element provided on at least one side of said substrate;
a first resin obtained by curing a first resin composition which fills a gap between said substrate and said semiconductor element; and
a second resin which covers said substrate and said first resin, and obtained by curing a second resin composition after said first resin composition is cured,
configured to ensure an adhesion strength between said first resin and said second resin of 18 MPa or larger at room temperature.

22. The semiconductor device as claimed in claim 21,
wherein said adhesion strength is 3 MPa or larger at 260° C.

23. A semiconductor device comprising:
a substrate;
a semiconductor element provided on at least one side of said substrate;
a first resin obtained by curing a first resin composition which fills the gap between said substrate and said semiconductor element; and
a second resin which covers said substrate, said semiconductor element and said first resin, and obtained by curing a second resin composition after said first resin composition is cured,
configured to ensure an adhesion strength between said first resin and said second resin of 3 MPa or larger at 260° C.

24. The semiconductor device as claimed in claim 21,
wherein said adhesion strength is 7 MPa or larger at 175° C.

25. The semiconductor device as claimed in claim 21,
wherein said first resin composition contains an epoxy resin which exists in liquid form at room temperature.

26. The semiconductor device as claimed in claim 21,
wherein said first resin composition contains a bisphenol-type epoxy resin.

27. The semiconductor device as claimed in claim 21,
wherein said first resin composition contains a multi-functional epoxy resin which has three or more epoxy groups per one molecule.

28. The semiconductor device as claimed in claim 21,
wherein said first resin further contains a hardener and a filler, and excludes any low-stress component.

29. The semiconductor device as claimed in claim 28,
wherein said low-stress component is solid rubber, liquid rubber or elastomer.

30. The semiconductor device as claimed in claim 21,
wherein said adhesion strength is 20 MPa or larger at room temperature.

31. The semiconductor device as claimed in claim 21,
wherein said adhesion strength is 4 MPa or larger at 260° C.

32. The semiconductor device as claimed in claim 21,
wherein said adhesion strength is 9 MPa or larger at 175° C.

33. A semiconductor device comprising:
a substrate;
a semiconductor element provided on at least one side of said substrate;
a first resin obtained by curing a first resin composition which fills the gap between said substrate and said semiconductor element; and
a second resin which covers said substrate, said semiconductor element and said first resin, and obtained by curing a second resin composition after said first resin composition is cured,
said first resin composition containing a multi-functional epoxy resin which has three or more epoxy groups per one molecule.

34. The semiconductor device as claimed in claim 33,
wherein said first resin further contains a hardener and a filler, and excludes any low-stress component.

35. The semiconductor device as claimed in claim 34,
wherein said low-stress component is solid rubber, liquid rubber or elastomer.

36. The semiconductor device as claimed in claim 21,
wherein said first resin covers at least a part of side faces of said semiconductor element.

37. The semiconductor device as claimed in claim 21,
wherein said semiconductor element has the top surface thereof remained exposed.

38. The semiconductor device as claimed in claim 33,
wherein said multi-functional epoxy resin is a tri-functional, glycidylamine-type epoxy resin.

39. The semiconductor device as claimed in claim 28,
wherein said filler is spherical silica.

40. A resin composition filling the gap between said substrate and semiconductor element of said semiconductor device described in claim 21.
